(19) United States
(12) Patent Application Publication
(10) Pub. No.: US 2010/0219834 A1
(43) Pub. Date: Sep. 2, 2010

(54) BIRDCAGE COIL WITH IMPROVED HOMOGENEITY AND REDUCED SAR

(75) Inventor: Kai-michael Luedeke, Halstenbek (DE)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 12/738,303

(22) PCT Filed: Oct. 15, 2008
(86) PCT No.: PCT/IB2008/054228

§ 371 Date: Apr. 16, 2010

(30) Foreign Application Priority Data
Oct. 17, 2007 (EP) 07118668.8

(51) Int. Cl. G01R 33/44

(52) U.S. Cl. 324/318

(57) ABSTRACT

A birdcage coil (10) for a magnetic resonance imaging device includes a plurality of rungs (12) coupled to a distal edge (15) of each of two endrings (16). The endrings (16) comprise a plurality of ring segments (18) that are separated by sets of capacitors (20, 22, 24). The rungs (12) are coupled to the endrings (16) by connector portions (14), which create a gap between the endrings (16) and the rungs (12). Additionally, the rungs (12) can be positioned over the capacitors (20, 22, 24), and the connector portions (14) can be shaped to offset the position of the rungs (12) relative to the ring segments (16) to which they are coupled to achieve a desire rung position relative to the capacitors (20, 22, 24).

### FIELD OF THE INVENTION

The present application finds particular application in subject imaging systems, particularly involving magnetic resonance imaging (MRI). However, it will be appreciated that the described technique may also find application in other imaging systems, other medical scenarios, or other medical techniques.

### BACKGROUND

Conventional birdcage coil designs employ rungs and endrings in the form of flat metal strips attached to a carrier structure. It has been found that wide rungs and even wider rings are advantageous for achieving high power sensitivity. The homogeneity of the radio frequency (RF) magnetic field is improved and the specific absorption rate (SAR) in the patient (e.g., due to RF electrical fields) is reduced, when the endrings are positioned closer to the RF screen than the rungs. See, e.g.: “An Elevated Endring Birdcage Coil for Improved Performance at 3 Tesla”, D. Weyers, D. Keren, E. Boskamp, G. McKinnon, K. Kinsey, Proc. Intl. Soc. Mag. Reson. Med. 11 (2004), p. 1548; US patent application US2005/0107684 A1, “Elevated Endring Birdcage Antenna For MRI Applications”, D. J. Weyers, D. Keren, K. Kinsey, B. Boskamp.

However, such designs are limited in that rung width and endring width can only be increased so far before image degradation begins to occur. That is, when the total length of a birdcage coil has been fixed for other structural reasons, widening the endrings reduces the effective rung length. Consequently, there has been a tradeoff between the advantages of wider endrings vs. the advantages of longer rungs.

The present application provides new and improved birdcage coil systems and methods that reduce SAR, which have the advantages of both wider rings and longer rungs, and which overcome the above-referenced problems and others.

### SUMMARY OF THE INVENTION

In accordance with one aspect, a birdcage coil for a magnetic resonance imager includes two endrings positioned around a central axis, each endring having an inner edge and a distal edge. A plurality of rungs are connected to the endrings, having a length greater than an axial distance between the inner edges of the endrings extending parallel to the central axis and terminating at a point contiguous to the distal edge of each endring, the rungs defining a cylinder having a diameter smaller than the diameter of the endrings. The coil further includes connector portions at each end of each rung, which couple each respective rung to the distal edge of each respective endring. In one embodiment, the rungs are positioned over the capacitors while connected to the ring segments.

One advantage is that B₁ field strength is increased.

Another advantage resides in improved axial homogeneity.

Another advantage resides in a larger usable extent in the axial direction and reduced SAR in those parts of the patient's body that come close to the rungs and endrings of the coil.

Still further advantages of the subject innovation will be appreciated by those of ordinary skill in the art upon reading and understand the following detailed description.

The innovation may take form in various components and arrangements of components, and in various steps and arrangements of steps. The drawings are only for purposes of illustrating various aspects and are not to be construed as limiting the invention.

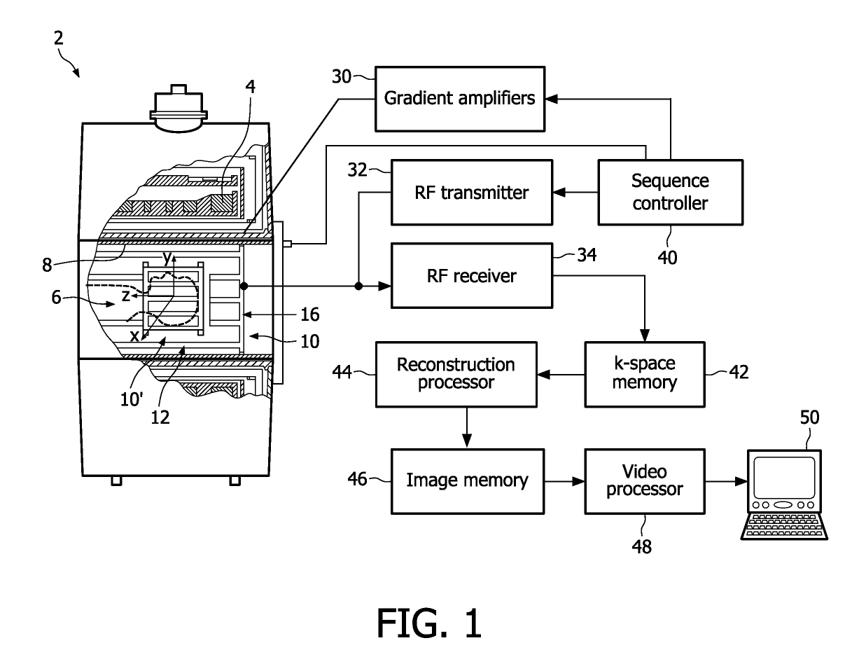

FIG. 1 illustrates an exemplary subject imaging device, such as may be employed in conjunction with the various coil structures described herein.

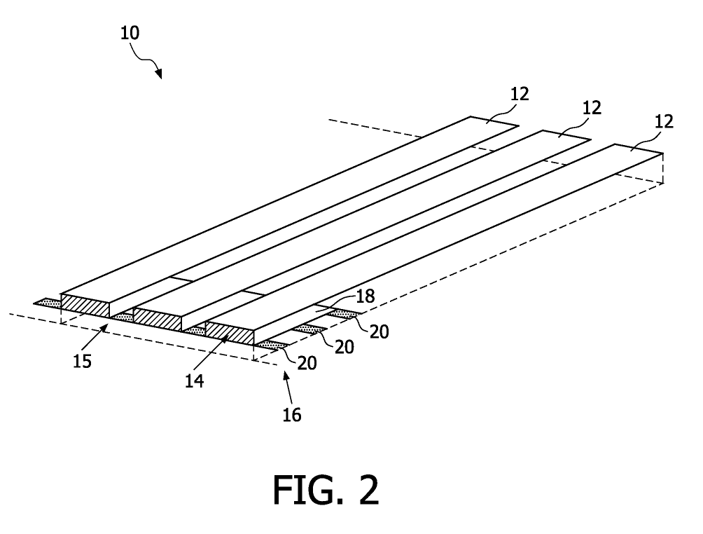

FIG. 2 illustrates a portion of a birdcage coil, which includes a plurality of rungs that extend in parallel to each other and are coupled at each end to a distal edge of an endring.

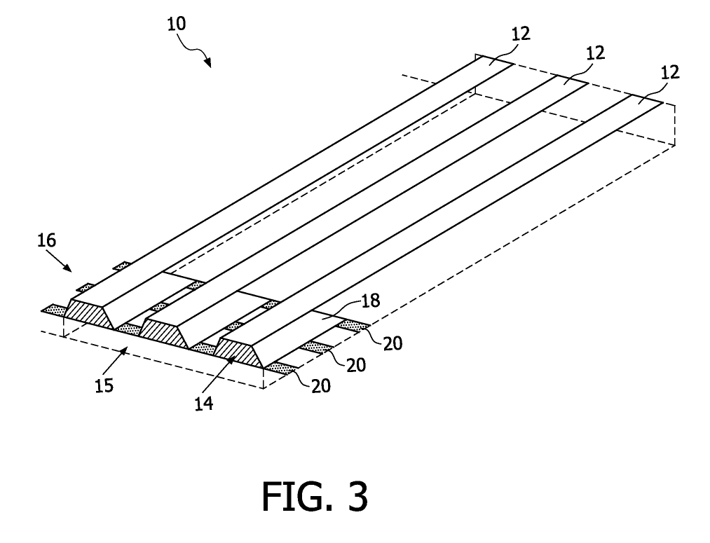

FIG. 3 illustrates another embodiment of the birdcage coil, in which the rungs are narrower than the ring segments.

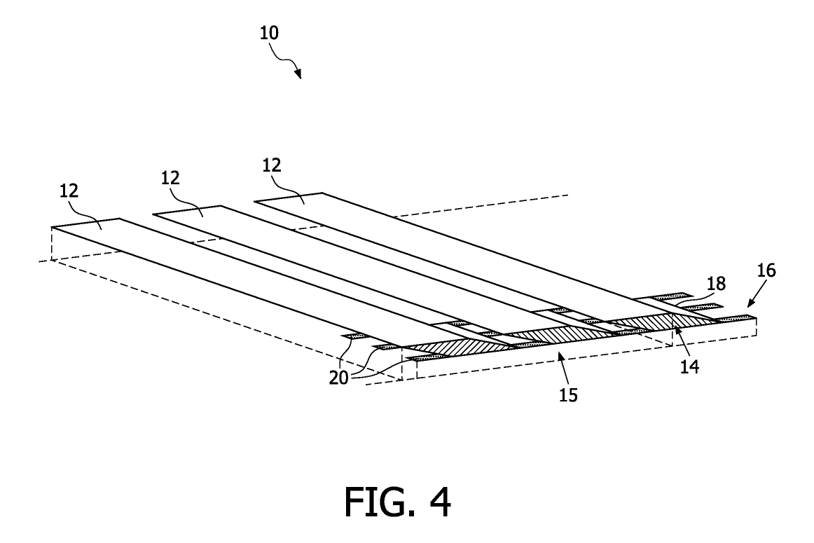

FIG. 4 illustrates a portion of a birdcage coil in which the rungs are offset relative to the ring segments such that the rungs are positioned substantially over the ring capacitors.

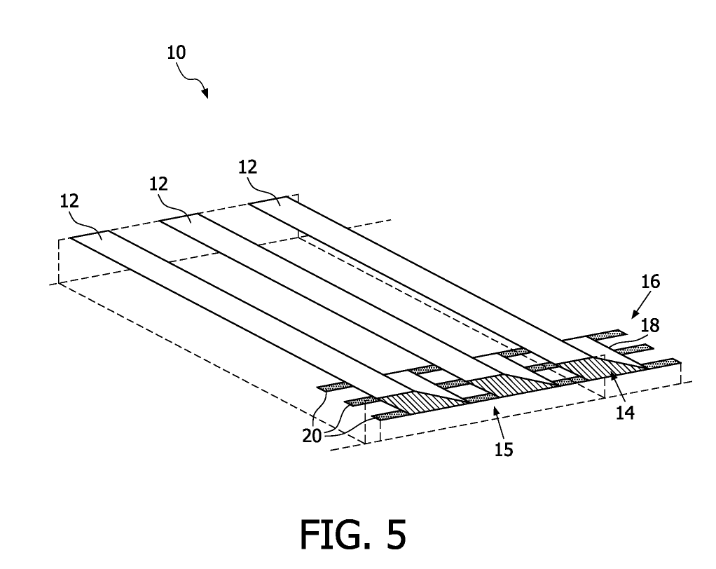

FIG. 5 is an illustration of the portion of the birdcage wherein each connector portion has an irregular trapezoid shape with parallel rung-side and ring-side edges, but with non-congruent opposing edges that span a distance between the rung and the endring.

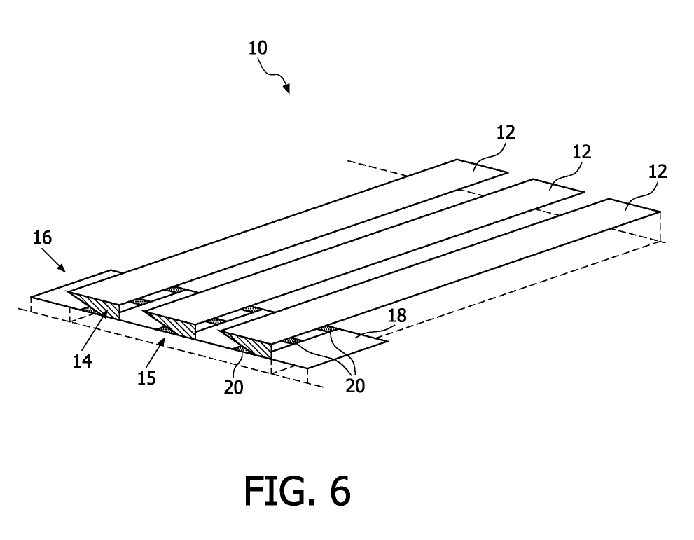

FIG. 6 illustrates the portion of the birdcage coil wherein the connector portion has a trapezoidal shape that facilitates positioning the rung to overlap the ring capacitors, as well as a portion of the rung segment to which the connector portion is attached.

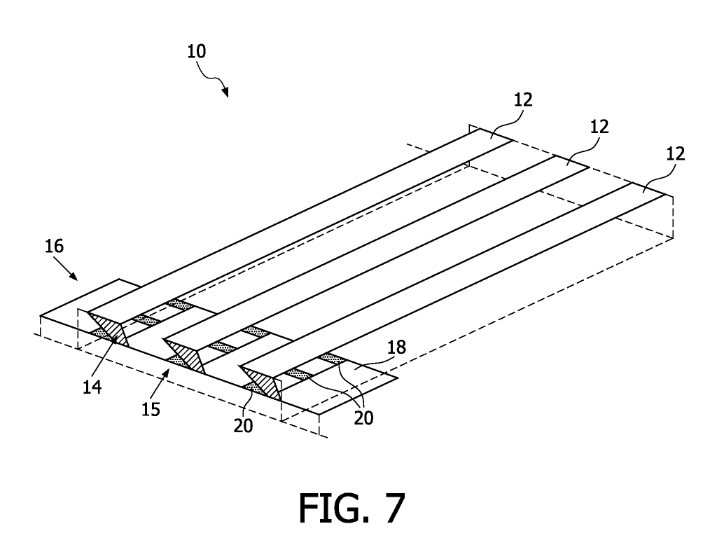

FIG. 7 illustrates the portion of a birdcage coil in which the connector portion has a non-uniform trapezoidal shape that positions the rung substantially over the capacitors without substantially overlapping the ring segment to which the connector portion is attached.

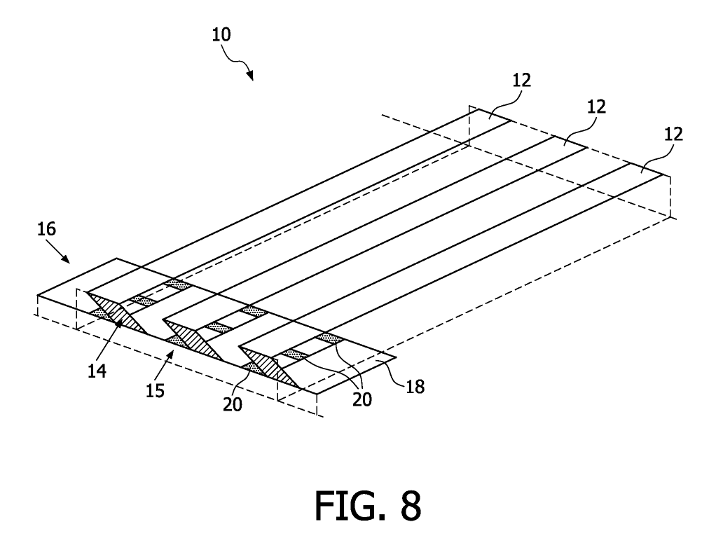

FIG. 8 illustrates the portion of a birdcage coil in which the connector portion has a parallelogram shape that positions the rung substantially over the capacitors without overlapping the ring segment to which the connector portion is attached.

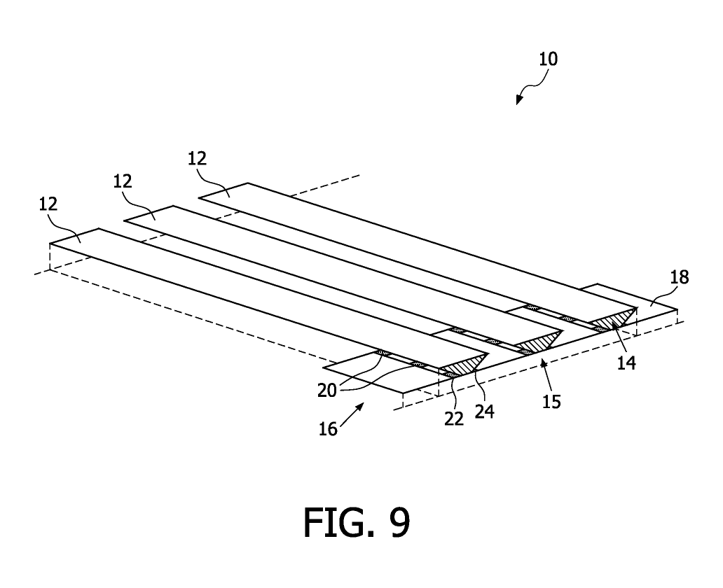

FIG. 9 illustrates the portion of the birdcage coil wherein the endring capacitors at the distal edges are replaced by a series connection of two capacitors and, and the connector portions are connected to their center junctions.

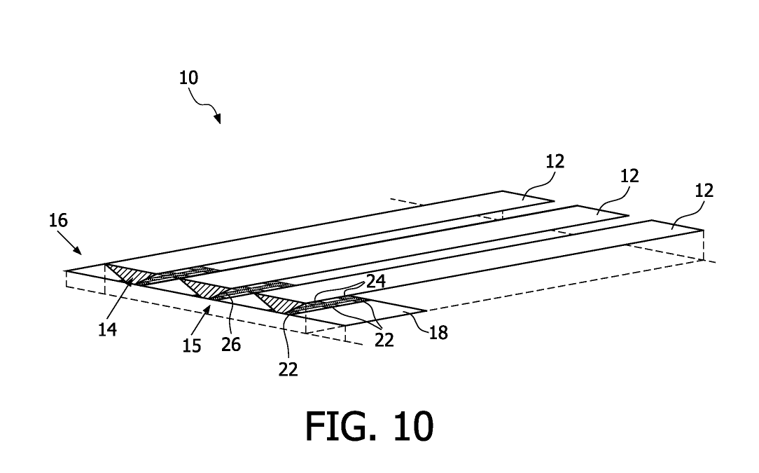

FIG. 10 illustrates the portion of the birdcage coil wherein some or all of the ring capacitors are replaced by pairs of capacitors of suitably increased values, and the center junctions connected with a metal strip running to the distal edge of the ring segment and the connection to the connector portion.

### DETAILED DESCRIPTION

The systems and methods described herein facilitate improving sensitivity and homogeneity while reducing of SAR in a bird cage coil for a magnetic resonance imaging (MRI) system, as well as improving coil performance using a variety of design features. In accordance with various aspects, rungs of a birdcage coil are coupled to distal (e.g., relative to the center of the birdcage coil) edges of endrings, rather than to the inner edges of the endrings as is common with conventional birdcage designs. This allows production of a more compact coil while maximizing or optimizing the rung lengths and the endring width. The structures described herein thus reduce the length of the birdcage by twice the endring width. Moreover, the described coil structures can facilitate reducing the “effective volume” of the coil and achieving correspondingly higher power sensitivity.

With reference to FIG. 1, a magnetic resonance (MR) scanner 2 is illustrated, which can be employed with the various coil assemblies described herein. The MR scanner includes a cylindrical main magnet assembly 4. The main magnet assembly 4 may be a superconducting cryoshielded solenoid, defining a bore 6 into which a subject is placed for imaging. The main magnet assembly 4 produces a substantially constant main magnetic field oriented along a longitudinal axis of the bore 6. Although a cylindrical main magnet assembly 4 is illustrated, it is to be understood that other magnet arrangements, such as vertical field, open magnets, non-superconducting magnets, and other configurations are also contemplated.

A gradient coil 8 produces magnetic field gradients in the bore 6 for spatially encoding magnetic resonance signals, for producing magnetization-spoiling field gradients, or the like. Preferably, the magnetic field gradient coil 8 includes coil segments configured to produce magnetic field gradients in three orthogonal directions, typically longitudinal or z, transverse or x, and vertical or y directions.

A whole body radio frequency coil assembly 10 (e.g., a birdcage coil assembly) generates radio frequency pulses for exciting magnetic resonance in dipoles of the subject. The radio frequency coil assembly 10 also serves to detect magnetic resonance signals emanating from the imaging region. Additionally, an optional local coil is illustrated within the bore 6 for more sensitive, localized spatial encoding, excitation, and reception of magnetic resonance signals. Various types of coil arrays are contemplated, such as a simple surface RF coil with one output, a quadrature coil assembly with two outputs, a phased array with several outputs, a SENSE coil array with dozens of outputs, combined RF and gradient coils with both outputs and inputs, and the like. The birdcage coil 10 and/or the local coil 10′ include a plurality of rungs 12 that are coupled to distal edges of an interior surface of a pair of endrings 16, as illustrated in the cutaway view of FIG. 1. Gradient pulse amplifiers 30 deliver controlled electrical currents to the magnetic field gradient coils 8 to produce selected magnetic field gradients. The gradient amplifiers also deliver electrical pulses to the gradient coils of local coil arrays that are equipped with gradient coils. A radio frequency transmitter 32, analog or digital, applies radio frequency pulses or pulse packets to the radio frequency coil assembly 10 to generate selected magnetic resonance excitations. A radio frequency receiver 34 is coupled to the local coil 10′ to receive and demodulate the induced magnetic resonance signals. Optionally, the whole body coil 10 is connected to the receiver in a wired or wireless interconnection.

To acquire magnetic resonance imaging data of a subject, the subject is placed inside the magnet bore 6, with the imaged region at or near an isocenter of the main magnetic field. A sequence controller 40 communicates with the gradient amplifiers 30 and the radio frequency transmitter 32 to produce selected transient or steady-state magnetic resonance sequences, to spatially encode such magnetic resonances, to selectively spoil magnetic resonances, or otherwise generate selected magnetic resonance signals characteristic of the subject. The generated magnetic resonance signals are detected by the local coil 10′, communicated to the radio frequency receiver 34, and stored in a k-space memory 42. The imaging data is reconstructed by a reconstruction processor 44 to produce an image representation that is stored in an image memory 46. In one suitable embodiment, the reconstruction processor 44 performs an inverse Fourier transform reconstruction.

The resultant image representation is processed by a video processor 48 and displayed on a user interface 50 equipped with a human readable display. The interface 50 is preferably a personal computer or workstation. Rather than producing a video image, the image representation can be processed by a printer driver and printed, transmitted over a computer network or the Internet, or the like. Preferably, the user interface 50 also allows a radiologist or other operator to communicate with the magnetic resonance sequence controller 40 to select magnetic resonance imaging sequences, modify imaging sequences, execute imaging sequences, and so forth.

With regard to FIG. 2, an enlarged end portion of the birdcage coil 10 is illustrated, which includes a plurality of rungs 12 that extend in parallel to each other and are coupled at each end by a connector portion 14 to an outer edge 15 of an endring 16. In order to simplify FIGS. 2-10, the rungs and ring segments are depicted as being flat above a plane surface rather than in the actual cylindrical arrangement in which they are employed. Additionally, with regard to the shape of the connector portions 14 (e.g., rectangular, trapezoidal, parallelogram, etc.), it is to be understood that such descriptions apply to the simplified planar figures herein, and that the parallel edges of the connector portion that couple to the rung and the endring can be curved to be congruent to cylindrical endrings. In one embodiment, the rungs are composed of metal areas deposited on a cylindrical carrier structure, in which case the connector portions have curved edges that correspond to the curvature of the endrings and the rungs. Alternatively, such edges can be straight in an embodiment that employs polygonal endrings.

Although not illustrated, it is to be understood that a like endring assembly is disposed at the other end of the rungs 12. The structure of the birdcage coil 10 increases the Bᵢ field strength, improves axial homogeneity, and shifts the limits of the usable volume farther out axially. In one embodiment, the ring segments have a circumferential length that is substantially equal to the width of the rungs. A connector portion 14 is substantially orthogonal to both its rung and the endring, although supplementary angle combinations other than approximately 90° can be employed to couple the rung to the endring. For instance, each rung can extend slightly past the outer or distal edge of the endring, causing the rung to form an angle of approximately X° with the connector portion, while the connector portion connects to the endring at an angle of approximately Y°, where X+Y equals 180°. Alternatively, the rung can have a length that is shorter than the distance between outer edges of two endrings, such that X is less than Y and X+Y=180°. In still other embodiments, the connector portion is curved in one or more planes.

The endring 16 comprises a plurality of ring segments 18 to which the connector portions 14 are coupled, and which are interspersed with capacitors 20. For example, three capacitors can be spaced approximately equally from the inner edge of the endring to the distal edge thereof. It will be appreciated that more or fewer capacitors may be placed between respective ring portions 18. Connections between the capacitors and the ring segments can be soldered or made by some other suitable technique.

The illustrated portion 10 represents a segment of the cylindrical birdcage, including two cylindrical endrings spaced apart by a predefined distance, each of which includes a predetermined number of ring segments 18. In one example, the endring 16 is continuous (e.g., having only one continuous ring segment 18) and has no capacitors, while each rung includes one or more capacitors (not shown), such as in a low-pass birdcage arrangement. In another example, each endring has N ring segments 18 arranged alternately with N sets of capacitors 20, where N is an integer, and N rungs do not include any capacitors, such as in a high-pass birdcage arrangement. In yet another example both the rungs and the endring comprise capacitors such as in a band-pass birdcage arrangement. In any case, the rungs are extended and connected to the axial positions of the distal edges of the endrings (relative to the isocenter).

FIG. 3 illustrates another embodiment of the birdcage coil 10, in which the rungs 12 are narrower (e.g., in a circumferential direction around a longitudinal axis of the birdcage) than the ring segments 18, and the connector portions 14 each have an isosceles trapezoid shape with a rung-side edge with a length approximately equal to the circumferential length of the rung and a ring-side edge with a length approximately equal to the width of the ring segment 18 to which the connector portion is attached. In this manner, rung width is not limited to being equal to ring segment circumferential length.

FIG. 4 illustrates a portion of a birdcage coil 10 in which the rungs 12 are offset relative to the ring segments 18 such that the rungs are positioned substantially over the ring capacitors 20, between the capacitors and the longitudinal axis of the birdcage coil. In this embodiment, each connector portion 14 is shaped as a parallelogram, such that the edges of the connector portion that connect to the rung and the distal edge 15 of the segments 18 of the endring 16 are substantially equal in length, as are the opposing edges. The parallelogram has a height to space the rungs from the endring by a desired or predetermined distance (e.g., a distance at which the rung is positioned radially inward to the endring). Optionally, the ring segments can be wider (e.g., in a circumferential direction) than the rungs.

FIG. 5 is an illustration of the portion of the birdcage coil 10 wherein each connector portion 14 has an irregular trapezoid shape with parallel rung-side and ring-side edges, but with non-congruent opposing edges that span a distance between the rung and the endring. In this embodiment, the ring segments are wider (e.g., in a circumferential direction) than the rungs. As with any of the connector portions described herein, the shape of each connector portion is designed to facilitate connecting a rung to a ring segment with minimal electrical losses and/or impedance, while mitigating disturbance to a generated magnetic field.

FIGS. 6-8 illustrate additional embodiments pertaining to the shape and/or orientation of the rungs 12, connector portions 14 as they are coupled to the endring segments 18. FIG. 6 illustrates the portion of the birdcage coil 10 wherein the connector portion 14 has a trapezoidal shape that facilitates positioning the rung 12 to overlap the ring capacitors 20, as well as a portion of the rung segment 18 to which the connector portion is attached. The connector portion has a rung-side edge with a length that corresponds to the width of the rung, and a shorter parallel ring-side edge that is coupled to the distal edge of the ring segment, adjacent to the capacitors 20. The other edges of the connector portion are of a desired length to achieve a predetermined height or distance between the rung and the ring segment and/or capacitors, and are congruent. FIG. 6, as well as FIGS. 7 and 8, differ from FIGS. 2-5 in that the connector portion 14 is attached to the ring segment over a fraction of the width of the ring segment.

FIG. 7 illustrates the portion of a birdcage coil 10 in which the connector portion 14 has a non-uniform trapezoidal shape that positions the rung 12 substantially over the capacitors 20. In one embodiment, the connector portion has a rung-side edge of a length substantially equal to the width of the rung, and a shorter parallel ring-side edge that is coupled to the distal edge of the ring segment, adjacent to the capacitors 20. In this embodiment, the ring segments are wider (e.g., in a circumferential direction) than the rungs. The other edges of the connector portion are of a desired length to achieve a predetermined height between the rung and the ring segment and/or capacitors, and are incongruent. For example, a capacitor-side edge of the connector portion is longer than a ring segment-side edge so that the rung is positioned substantially over the capacitors.

FIG. 8 illustrates the portion of a birdcage coil 10 in which the connector portion 14 has a parallelogram shape that positions the rung 12 substantially over the capacitors 20. In one embodiment, the connector portion has a rung-side edge of a length substantially equal to the width of the rung, and a substantially equally long parallel ring-side edge that is coupled to the distal edge of the ring segment, adjacent to the capacitors 20. In this embodiment, the ring segments are wider (e.g., in a circumferential direction) than the rungs. The other edges of the connector portion are of a desired length to achieve a predetermined distance between the rung and the ring segment and/or capacitors. FIG. 8 also illustrates the option of using rungs 12 that are longer than the axial spacing between the outer edges 15 of the endrings 16.

The structures of FIGS. 4-8 permit the rungs to serve as shields against electrical fields coming from the high voltages across the endring capacitors. This in turn leads to a reduction of SAR in sections of a patient's body coming close to the connector portions and endrings.

FIG. 9 illustrates the portion of the birdcage coil 10 wherein the endring capacitors at the distal edges are replaced by a series connection of two capacitors 22 and 24, and the connector portions 14 are connected to their center junctions. The remaining capacitors 20 positioned between ring segments 18 are retained (e.g., the center capacitor and the capacitor nearest the inner edge of the endring). Capacitors 22 and 24 can have approximately equal values, and can be selected to have values approximately twice that of capacitors 20, such that the total capacitance across capacitors 22 and 24, when connected in series, is approximately equally to that of respective capacitors 20. The birdcage structure of FIG. 8 mitigates a need for a slanted connection between the connector portions and the distal metal edges of the endring segments. The connection to the center “tap” of a split ring capacitor (e.g., as formed by capacitors 22 and 24) allows a symmetrical radial connection and halves the maximum voltage between any connector portion and the two neighboring ring sections.

FIG. 10 illustrates the portion of the birdcage coil 10 wherein some or all of the ring capacitors are replaced by pairs of capacitors 22, 24 of suitably increased values, and the center junctions connected with a metal strip 26 running to the distal edge of the ring segment 18 and the connection to the connector portion 14. The birdcage structure of FIG. 9 thereby also mitigates a need for a slanted connection between the connector portions and the distal metal edges of the endring sections. Similarly, connection to the center “tap” of a split ring capacitor (e.g., as formed by capacitors 22 and 24) allows a symmetrical radial connection and halves the maximum voltage between any connector portion and the two neighboring ring sections.

It will be appreciated that the rungs 12, connector portions 14, ring segments 18 and/or metal strips 26 can be formed of a single piece of material (e.g., metal, foil on a dielectric substrate, or the like), and shaped into a desired configuration according to any of the preceding figures as desired by a designer and/or according to predetermined design constraints, or by electrically connected sections. Multiple rungs with integral ring segments can then be joined by affixing ring capacitors to the respective ring segment portions to generate a desired birdcage coil configuration.

The innovation has been described with reference to several embodiments. Modifications and alterations may occur to others upon reading and understanding the preceding detailed description. It is intended that the innovation be construed as including all such modifications and alterations insofar as they come within the scope of the appended claims or the equivalents thereof.

1. A birdcage coil for a magnetic resonance imager, including:
two endrings positioned around a central axis, each endring having an inner edge and a distal edge;
a plurality of rungs having a length greater than an axial distance between the inner edges of the endrings extending parallel to the central axis and terminating at a point contiguous to the distal edge of each endring, the rungs defining a cylinder having a diameter smaller than the diameter of the endrings; and
a connector portion at each end of each rung, which couples each respective rung to the distal edge of each respective endring.

2. The birdcage coil according to claim 1, wherein each endring further includes a plurality of ring segments and plurality of capacitors that connect each pair of adjacent ring segments.

3. The birdcage coil of claim 2, wherein the rungs are positioned between the capacitors and an isocenter of the coil.

4. The birdcage coil according to claim 2, wherein the connector portion has curved edges corresponding to curvatures of the rung and the ring segment to which it is coupled, and connects the rung straight and symmetrically to the ring segment relative to an isocenter of the coil.

5. The birdcage coil according to claim 3, wherein the connector portion is substantially a parallelogram, with curved edges corresponding to curvatures of the rung and the ring segment to which it is coupled, the rung being positioned radially between the capacitors and the central axis.

6. The birdcage coil according to claim 3, wherein the connector portion is substantially a parallelogram, with curved edges corresponding to curvatures of the rung and the ring segment to which it is coupled, which is positioned over the plurality of capacitors at a predetermined height.

7. The birdcage coil according to claim 3, wherein the connector portion is substantially shaped as an isosceles trapezoid with curved edges corresponding to curvatures of the rung and the ring segment to which it is coupled.

8. The birdcage coil according to claim 3, wherein the connector portion is substantially shaped as an irregular trapezoid with curved edges corresponding to curvatures of the rung and the ring segment to which it is coupled.

9. The birdcage coil according to claim 2, wherein the endring further includes a pair of serially connected capacitors positioned adjacent to the distal edge of the endring between any two adjacent ring segments.

10. The birdcage coil according to claim 9, wherein the connector portion is coupled to the endring between the pair of capacitors.

11. The birdcage coil according to claim 10, wherein each rung is connected to a pair of ring segments by at least a pair of capacitors.

12. A magnetic resonance imaging system comprising:
a main magnet assembly;
a plurality of gradient coils; and
the birdcage coil according to claim 1.

13. The birdcage coil according to claim 2, wherein the connector portion is coupled to a metal strip at a point near the distal edge of the ring.

14. The birdcage coil according to claim 2, wherein the metal strip is coupled to a center tap between each of a plurality of serially connected pairs of capacitors.

15. The birdcage coil according to claim 14, wherein the connector portion is trapezoidal in shape, with a curved edge corresponding to curvature of the rung to which it is coupled, with a ring-side edge of a length approximately equal to the width of the metal strip and a rung-side edge approximately equal to the width of the rung.
